(19) United States
(12) Patent Application Publication
(10) Pub. No.: US 2025/0192109 A1
(43) Pub. Date: Jun. 12, 2025

(54) SEMICONDUCTOR PACKAGE

(71) Applicant: SAMSUNG ELECTRONICS CO., LTD., Suwon-si (KR)

(72) Inventor: Hyunsoo CHUNG, Suwon-si (KR)

(21) Appl. No.: 18/828,990

(22) Filed: Sep. 9, 2024

(30) Foreign Application Priority Data
Dec. 7, 2023 (KR) 10-2023-0176295

(51) Int. Cl. H01L 25/065; H01L 23/00; H01L 23/31; H01L 25/18; H05K 1/18; H10B 80/00

(52) U.S. Cl. CPC H01L 25/0657; H01L 23/3135; H01L 24/05; H01L 24/08; H01L 24/16; H01L 24/29; H01L 24/32; H01L 24/73; H01L 23/3171; H01L 24/80; H01L 25/0652; H01L 25/18; H01L 2224/05647; H01L 2224/08145; H01L 2224/16145; H01L 2224/29016; H01L 2224/29687; H01L 2224/32145; H01L 2224/73253; H01L 2224/80895; H01L 2224/80896; H01L 2225/06513; H01L 2225/06541; H01L 2924/1431; H01L 2924/1436; H05K 1/181; H10B 80/00

(57) ABSTRACT

A semiconductor package includes a buffer die, memory die stack structures sequentially stacked on the buffer die in a vertical direction, each of which includes a base core die and middle core dies stacked on the base core die in the vertical direction, a first mold layer on the base core die of each of the memory die stack structures and on sidewalls of the middle core dies, and a second mold layer on the buffer die, on sidewalls of the base core dies, and on a sidewall of the first mold layer. The buffer die has a first planar area, the base core die has a second planar area smaller than the first planar area, and each of the middle core dies has a third planar area smaller than the second planar area.

### CROSS-REFERENCE TO RELATED APPLICATION

This application claims priority under 35 U.S.C. § 119 to Korean Patent Application No. 10-2023-0176295, filed on Dec. 7, 2023 in the Korean Intellectual Property Office (KIPO), the disclosure of which is incorporated herein by reference in its entirety.

### BACKGROUND

### 1. Field

Example embodiments relate to a semiconductor package. More particularly, example embodiments relate to a multi-chip package including a plurality of stacked chips.

### 2. Description of the Related Art

A multi-chip package includes a plurality of chips stacked on a package substrate. A bonding layer containing a conductive pattern is disposed between the chips, and electrically connects the chips with each other. In the multi-chip package, the quality of bonding between the chips may be important in the electrical connection between the chips.

### SUMMARY

Example embodiments provide a semiconductor package having enhanced electrical characteristics.

According to example embodiments, there is provided a semiconductor package. The semiconductor package may include a buffer die, memory die stack structures sequentially stacked on the buffer die in a first direction (e.g., a vertical or upward direction), each of which may include a base core die and middle core dies stacked on the base core die in the first direction, a first mold layer on the base core die of each of the memory die stack structures and on sidewalls of the middle core dies, and a second mold layer on the buffer die, on sidewalls of the base core dies, and on a sidewall of the first mold layer. The buffer die may have a first planar area, the base core die may have a second planar area smaller than the first planar area, and each of the middle core dies may have a third planar area smaller than the second planar area.

According to example embodiments, there is provided a semiconductor package. The semiconductor package may include a lower semiconductor chip stack structure, an upper semiconductor chip stack structure, and a sixth semiconductor chip. The lower semiconductor chip stack structure may include a first semiconductor chip including a logic device, a second semiconductor chip on and bonded to the first semiconductor chip and including a memory device, and third semiconductor chips stacked on the second semiconductor chip in a first direction (e.g., a vertical or upward direction), each of which may include a memory device. The upper semiconductor chip stack structure may include a fourth semiconductor chip on and bonded to the lower semiconductor chip stack structure and including a memory device, and fifth semiconductor chips stacked on the fourth semiconductor chip in the first direction, each of which may include a memory device. The sixth semiconductor chip may be stacked on and bonded to the upper semiconductor chip stack structure. The sixth semiconductor chip may have a thickness in the first direction that is greater than that of each of the third and fifth semiconductor chips. The lower semiconductor chip stack structure and the upper semiconductor chip stack structure may be bonded to each other by a conductive bump. The third semiconductor chips may be bonded to each other by a first bonding pattern and a first bonding layer containing the bonding pattern, and the fifth semiconductor chips may be bonded to each other by a second bonding pattern and a second bonding layer containing the bonding pattern. Each of the third and fifth semiconductor chips may include a substrate having a first surface facing toward the first semiconductor chip and a second surface opposite the first surface, and wherein the memory device of each of the third and fifth semiconductor chips is beneath the second surface of the substrate.

According to example embodiments, there is provided a semiconductor package. The semiconductor package may include a logic chip, memory chip stack structures sequentially stacked on the logic chip in a first direction (e.g., a vertical or upward direction), each of which may include a first memory chip and second memory chips stacked on the first memory chip in the first direction, a third memory chip stacked on an uppermost one of the memory chip stack structures, a first mold layer on the first memory chip of each of the memory chip stack structures and on sidewalls of the second memory chips, and a second mold layer on the logic chip, on sidewalls of the first memory chips, on a sidewall of the third memory chip, and on a sidewall of the first mold layer. Neighboring ones of the memory chip stack structures in the first direction may be bonded to each other by a conductive bump. Neighboring ones of the second memory chips in the first direction may be bonded to each other by a first bonding pattern including copper and a first bonding layer containing the first bonding pattern.

In the semiconductor package in accordance with example embodiments, the semiconductor chips stacked in the first direction (e.g., a vertical or upward direction) may be divided into a several groups, the semiconductor chip in each of the groups may be bonded to each other by an HCB process, while the groups may be bonded to each other by a TCB process. Thus, the bonding state between the semiconductor chips may be enhanced and the structural stability of the semiconductor package may be enhanced.

### BRIEF DESCRIPTION OF THE DRAWINGS

FIG. 1 is a cross-sectional view illustrating a semiconductor package in accordance with example embodiments.

FIGS. 2 to 11 are cross-sectional views illustrating a method of manufacturing a semiconductor package in accordance with example embodiments.

FIGS. 12 to 14 are cross-sectional views illustrating semiconductor packages in accordance with example embodiments, which may correspond to FIG. 1.

FIG. 15 is a cross-sectional view illustrating an electronic device in accordance with example embodiments.

### DETAILED DESCRIPTION OF EXAMPLE EMBODIMENTS

Hereinafter, example embodiments will be explained in detail with reference to the accompanying drawings. Hereinafter, a direction substantially parallel to an upper surface of a wafer or a substrate may be referred to as a horizontal direction, and a direction substantially perpendicular to the upper surface of the wafer or the substrate may be referred to as a vertical direction.

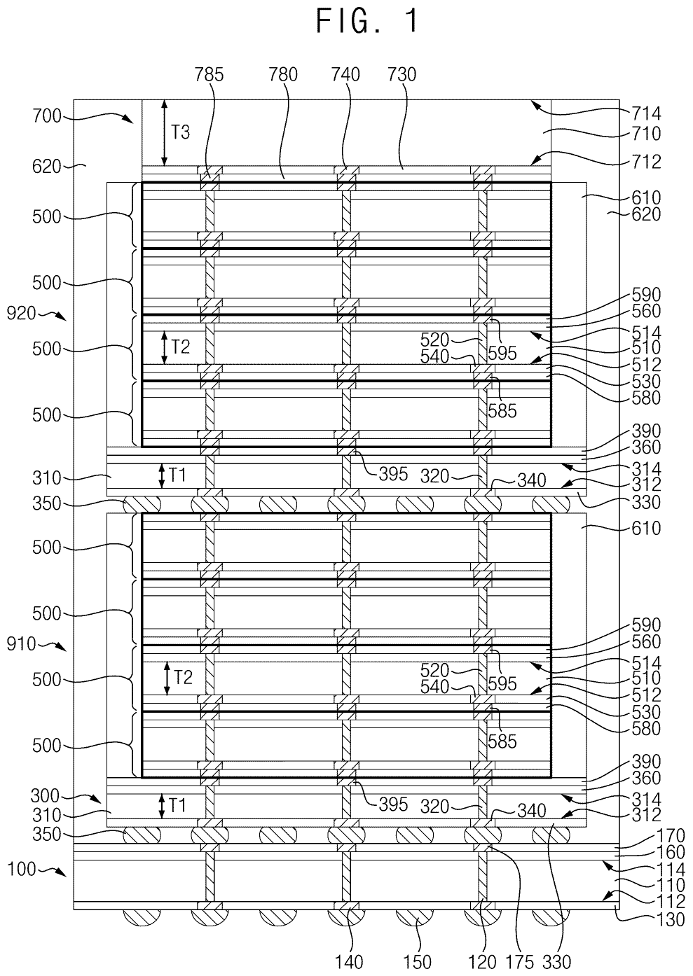

FIG. 1 is a cross-sectional view illustrating a semiconductor package in accordance with example embodiments.

Referring to FIG. 1, the semiconductor package may include a first semiconductor chip 100, a lower semiconductor chip stack structure 910, an upper semiconductor chip stack structure 920 and a fourth semiconductor chip 700 sequentially stacked on the first semiconductor chip 100 in the vertical direction and first and second mold layers 610 and 620, and each of the lower and upper semiconductor chip stack structures 910 and 920 may include a plurality of third semiconductor chips 500 sequentially stacked in the vertical direction.

In example embodiments, the first semiconductor chip 100 may be a buffer die, and may include a logic device, e.g., a controller. Each of the second to fourth semiconductor chips 300, 500 and 700 may be a core die, and may include a memory device. Thus, the first semiconductor chip 100 may also be referred to as a logic die or a logic chip, and each of the second to fourth semiconductor chips 300, 500 and 700 may also be referred to as a memory die or a memory chip.

Each of the second and third semiconductor chips 300 and 500 may be a middle core die, and the fourth semiconductor chip 700 may be a top core die. However, a plurality of third semiconductor chips 500 may be stacked on the second semiconductor chip 300, and thus the second semiconductor chip 300 may also be referred to as a base core die.

FIG. 1 shows that the semiconductor package includes two semiconductor chip stack structures stacked in the vertical direction on the first semiconductor chip 100, that is, the lower semiconductor chip stack structure 910 and the upper semiconductor chip stack structure 920, however, the inventive concept may not be limited thereto. In some embodiments, the semiconductor package may include more than two semiconductor chip stack structures stacked in the vertical direction on the first semiconductor chip 100, and the fourth semiconductor chip 700 may be stacked on an uppermost one of the semiconductor chip stack structures.

Each of the semiconductor chip stack structures may also be referred to as a memory die stack structure or a memory chip stack structure.

In each of the lower and upper semiconductor chip stack structures 910 and 920, the third semiconductor chips 500 stacked in the vertical direction on the second semiconductor chip 300 may form a third semiconductor chip structure. In example embodiments, the number of the third semiconductor chips 500 included in the third semiconductor chip structure may be limited to a given value. In an example embodiment, the third semiconductor chip structure may include equal to or less than four third semiconductor chips 500.

The third semiconductor chip structure may also be referred to as a middle core die.

In example embodiments, the semiconductor package may be a high bandwidth memory (HBM) package.

The first semiconductor chip 100 may include a first substrate 110 having first and second surfaces 112 and 114 opposite to each other in the vertical direction, a first through electrode 120 extending through the first substrate 110, a first insulating interlayer and a second insulating interlayer 130 sequentially stacked downwardly in the vertical direction beneath the first surface 112 of the first substrate 110, a first protective pattern structure 160 on the second surface 114 of the first substrate 110, a conductive pad 175 on the first through electrode 120, a passivation layer 170 on the first protective pattern structure 160 and covering a sidewall of the conductive pad 175, and a first conductive connection member 150 beneath the second insulating interlayer 130.

The first substrate 110 may include a semiconductor material, e.g., silicon, germanium, silicon-germanium, or a III-Vgroup compound semiconductor, e.g., GaP, GaAs, GaSb, etc. In example embodiments, the first substrate 110 may be a silicon-on-insulator (SOI) substrate or a germanium-on-insulator (GOI) substrate.

The first substrate 110 may have a first planar area in the horizontal direction.

A circuit device, e.g., a logic device may be formed beneath the first surface 112 of the first substrate 110, and thus the first surface 112 may be an active surface of the first substrate 110. The circuit device may include circuit patterns, which may be covered by the first insulating interlayer.

The second insulating interlayer 130 may contain a first wiring structure 140 therein. The first wiring structure 140 may include, e.g., wirings, vias, contact plugs, etc., at a plurality of levels, however, the first wiring structure 140 is shown as a single structure in FIG. 1 for the brevity of the drawing.

The first conductive connection member 150 may be formed beneath the second insulating interlayer 130, and may contact the first wiring structure 140 to be electrically connected thereto. In example embodiments, a plurality of first conductive connection members 150 may be spaced apart from each other in the horizontal direction. The first conductive connection member 150 may be a conductive bump including, e.g., solder.

The first through electrode 120 may extend through the first substrate 110 in the vertical direction, and may include a protrusion portion that may protrude upwardly in the vertical direction over the second surface 114 of the first substrate 110, as illustrated in FIG. 1. In example embodiments, a plurality of first through electrodes 120 may be spaced apart from each other in the horizontal direction, and each of the first through electrodes 120 may include a shape of, e.g., a circle, an ellipse, a polygon, a polygon with rounded corners, etc., in a plan view (e.g., in a plan view of a cross-section of the first through electrodes 120).

In an example embodiment, the first through electrode 120 may extend through the first substrate 110, and may contact a portion of the circuit patterns in the first insulating interlayer to be electrically connected thereto. Alternatively, the first through electrode 120 may extend through the first substrate 110 and the first insulating interlayer, and may contact a portion of the first wiring structure 140 in the second insulating interlayer 130 to be electrically connected thereto.

The first protective pattern structure 160 may be formed on the second surface 114 of the first substrate 110, and may surround the protrusion portion of the first through electrode 120, as illustrated in FIG. 1. In an example embodiment, the first protective pattern structure 160 may include first and second protective patterns stacked in the vertical direction. The first protective pattern may include an oxide, e.g., silicon oxide, and the second protective pattern may include an insulating nitride, e.g., silicon nitride.

The conductive pad 175 may contact an upper surface of the first through electrode 120, and a plurality of conductive pads 175 may be spaced apart from each other in the horizontal direction according to the layout of the first through electrodes 120. The passivation layer 170 may include an oxide, e.g., silicon oxide, or an insulating nitride, e.g., silicon nitride, silicon oxynitride, silicon carbonitride, etc.

The first conductive connection member 150 may include a metal, e.g., aluminum, copper, nickel, silver, etc., the first insulating interlayer and the second insulating interlayer 130 may include, e.g., silicon oxide or a low-k dielectric material such as an oxide doped with carbon or fluorine. The first through electrode 120, and the wirings, the vias and the contact plugs included in the first wiring structure 140 may include, e.g., a metal, a metal nitride, a metal silicide, etc.

The second semiconductor chip 300 may include a second substrate 310 having first and second surfaces 312 and 314 opposite to each other in the vertical direction, a second through electrode 320 extending through the second substrate 310, a third insulating interlayer and a fourth insulating interlayer 330 sequentially stacked downwardly in the vertical direction beneath the first surface 312 of the second substrate 310, a second protective pattern structure 360 on the second surface 314 of the second substrate 310, a first bonding pattern 395 on the second through electrode 320, a first bonding layer 390 on the second protective pattern structure 360 and covering a sidewall of the first bonding pattern 395, and a second conductive connection member 350 beneath the fourth insulating interlayer 330.

The second substrate 310 may include a semiconductor material, e.g., silicon, germanium, silicon-germanium, or a III-V group compound semiconductor, e.g., GaP, GaAs, GaSb, etc. In example embodiments, the second substrate 310 may be a silicon-on-insulator (SOI) substrate or a germanium-on-insulator (GOI) substrate.

The second substrate 310 may have a first thickness T1 in the vertical direction, and may have a second planar area in the horizontal direction. In example embodiments, the second planar area of the second substrate 310 may be smaller than the first planar area of the first substrate 110.

A circuit device, e.g., a volatile memory device such as DRAM device, SRAM device, etc., or a non-volatile memory device such as flash memory device, EEPROM device, etc., may be formed beneath the first surface 312 of the second substrate 310, and thus the first surface 312 of the second substrate 310 may be an active surface. The circuit device may include circuit patterns, which may be covered by the third insulating interlayer.

The fourth insulating interlayer 330 may contain a second wiring structure 340 therein. The second wiring structure 340 may include, e.g., wirings, vias, contact plugs, etc., at a plurality of levels, however, the second wiring structure 340 is shown as a single structure in FIG. 1 for the brevity of the drawing.

The second conductive connection member 350 may be formed beneath the fourth insulating interlayer 330, and may contact a portion of the second wiring structure 340 to be electrically connected thereto. In example embodiments, a plurality of second conductive connection members 350 may be spaced apart from each other in the horizontal direction. The second conductive connection member 350 may be a conductive bump including, e.g., solder.

The second through electrode 320 may extend through the second substrate 310 in the vertical direction, and may include a protrusion portion that may protrude upwardly in the vertical direction over the second surface 314 of the second substrate 310, as illustrated in FIG. 1. In example embodiments, a plurality of second through electrodes 320 may be spaced apart from each other in the horizontal direction, and each of the second through electrodes 320 may include a shape of, e.g., a circle, an ellipse, a polygon, a polygon with rounded corners, etc., in a plan view (e.g., in a plan view of a cross-section of the first through electrodes 120).

In an example embodiment, the second through electrode 320 may extend through the second substrate 310, and may contact a portion of the circuit patterns in the third insulating interlayer to be electrically connected thereto. Alternatively, the second through electrode 320 may extend through the second substrate 310 and the third insulating interlayer, and may contact a portion of the second wiring structure 340 in the fourth insulating interlayer 330 to be electrically connected thereto.

The second protective pattern structure 360 may be formed on the second surface 314 of the second substrate 310, and may surround the protrusion portion of the second through electrode 320, as illustrated in FIG. 1. In an example embodiment, the second protective pattern structure 360 may include third and fourth protective patterns stacked in the vertical direction. The third protective pattern may include an oxide, e.g., silicon oxide, and the fourth protective pattern may include an insulating nitride, e.g., silicon nitride.

The first bonding pattern 395 may contact an upper surface of the second through electrode 320, and a plurality of first bonding patterns 395 may be spaced apart from each other in the horizontal direction according to the layout of the second through electrodes 320. The first bonding layer 390 may be formed on the second protective pattern structure 360, and may cover a sidewall of the first bonding pattern 395, as illustrated in FIG. 1. The first bonding pattern 395 may include a metal, e.g., copper, and the first bonding layer 390 may include an insulating nitride, e.g., silicon carbonitride or an oxide, e.g., silicon oxide.

The second conductive connection member 350 may include a metal, e.g., aluminum, copper, nickel, silver, etc., the third insulating interlayer and the fourth insulating interlayer 330 may include, e.g., silicon oxide or a low-k dielectric material such as an oxide doped with carbon or fluorine. The second through electrode 320, and the wirings, the vias and the contact plugs included in the second wiring structure 340 may include, e.g., a metal, a metal nitride, a metal silicide, etc.

The third semiconductor chip 500 may include a third substrate 510 having first and second surfaces 512 and 514 opposite to each other in the vertical direction, a third through electrode 520 extending through the third substrate 510, a fifth insulating interlayer and a sixth insulating interlayer 530 sequentially stacked downwardly in the vertical direction beneath the first surface 512 of the third substrate 510, a second bonding layer 580 beneath the sixth insulating interlayer 530 and containing a second bonding pattern 585, a third protective pattern structure 560 on the second surface 514 of the third substrate 510, a third bonding pattern 595 on the third through electrode 520, and a third bonding layer 590 on the third protective pattern structure 560 and covering a sidewall of the third bonding pattern 595.

The third substrate 510 may include a semiconductor material, e.g., silicon, germanium, silicon-germanium, or a III-V group compound semiconductor, e.g., GaP, GaAs, GaSb, etc. In example embodiments, the third substrate 510 may be a silicon-on-insulator (SOI) substrate or a germanium-on-insulator (GOI) substrate.

The third substrate 510 may have a second thickness T2 in the vertical direction, and may have a third planar area in the horizontal direction. In example embodiments, the second thickness T2 of the third substrate 510 may be greater than the first thickness T1 of the second substrate 310. Additionally, the third planar area of the third substrate 510 may be smaller than the second planar area of the second substrate 310.

A circuit device, e.g., a volatile memory device such as DRAM device, SRAM device, etc., or a non-volatile memory device such as flash memory device, EEPROM device, etc., may be formed beneath the first surface 512 of the third substrate 510, and thus the first surface 512 of the third substrate 510 may be an active surface. The circuit device may include circuit patterns, which may be covered by the fifth insulating interlayer.

The sixth insulating interlayer 530 may contain a third wiring structure 540 therein. The third wiring structure 540 may include, e.g., wirings, vias, contact plugs, etc., at a plurality of levels, however, the third wiring structure 540 is shown as a single structure in FIG. 1 for the brevity of the drawing.

The second bonding layer 580 may be formed beneath the sixth insulating interlayer 530, and may cover a sidewall of the second bonding pattern 585, as illustrated in FIG. 1. The second bonding pattern 585 may contact a portion of the third wiring structure 540 in the sixth insulating interlayer 530, and may be electrically connected thereto.

The third through electrode 520 may extend through the third substrate 510 in the vertical direction, and may include a protrusion portion that may protrude upwardly in the vertical direction over the second surface 514 of the third substrate 510, as illustrated in FIG. 1. In example embodiments, a plurality of third through electrodes 520 may be spaced apart from each other in the horizontal direction, and each of the third through electrodes 520 may include a shape of, e.g., a circle, an ellipse, a polygon, a polygon with rounded corners, etc., in a plan view (e.g., in a plan view of a cross-section of the first through electrodes 120).

In an example embodiment, the third through electrode 520 may extend through the third substrate 510, and may contact a portion of the circuit patterns in the fifth insulating interlayer to be electrically connected thereto. Alternatively, the third through electrode 520 may extend through the third substrate 510 and the fifth insulating interlayer, and may contact a portion of the third wiring structure 540 in the sixth insulating interlayer 530 to be electrically connected thereto.

The third protective pattern structure 560 may be formed on the second surface 514 of the third substrate 510, and may surround the protrusion portion of the third through electrode 520, as illustrated in FIG. 1. In an example embodiment, the third protective pattern structure 560 may include fifth and sixth protective patterns stacked in the vertical direction. The fifth protective pattern may include an oxide, e.g., silicon oxide, and the sixth protective pattern may include an insulating nitride, e.g., silicon nitride.

The third bonding pattern 595 may contact an upper surface of the third through electrode 520, and a plurality of third bonding patterns 595 may be spaced apart from each other in the horizontal direction according to the layout of the third through electrodes 520. The third bonding layer 590 may be formed on the third protective pattern structure 560, and may cover a sidewall of the third bonding pattern 595, as illustrated in FIG. 1.

Each of the second and third bonding patterns 585 and 595 may include a metal, e.g., copper, and each of the second and third bonding layers 580 and 590 may include an insulating nitride, e.g., silicon carbonitride or an oxide, e.g., silicon oxide.

Each of the fifth insulating interlayer and the sixth insulating interlayer 530 may include, e.g., silicon oxide or a low-k dielectric material, e.g., an oxide doped with carbon or fluorine. The third through electrode 520, and the wirings, the vias and the contact plugs included in the third wiring structure 540 may include a conductive material, e.g., a metal, a metal nitride, a metal silicide, etc.

The fourth semiconductor chip 700 may include a fourth substrate 710 having first and second surfaces 712 and 714 opposite to each other in the vertical direction, a seventh insulating interlayer and an eighth insulating interlayer 730 sequentially stacked downwardly in the vertical direction beneath the first surface 712 of the fourth substrate 710, and a fourth bonding layer 780 beneath the eighth insulating interlayer 730 and containing a fourth bonding pattern 785.

The fourth substrate 710 may include a semiconductor material, e.g., silicon, germanium, silicon-germanium, or a III-V group compound semiconductor, e.g., GaP, GaAs, GaSb, etc. In example embodiments, the fourth substrate 710 may be a silicon-on-insulator (SOI) substrate or a germanium-on-insulator (GOI) substrate.

The fourth substrate 710 may have a third thickness T3 in the vertical direction, and may have a fourth planar area in the horizontal direction. In example embodiments, the third thickness T3 of the fourth substrate 710 may be greater than the second thickness T2 of the third substrate 510. Additionally, the fourth planar area of the fourth substrate 710 may be substantially the same as the third planar area of the third substrate 510.

A circuit device, e.g., a volatile memory device such as DRAM device, SRAM device, etc., or a non-volatile memory device such as flash memory device, EEPROM device, etc., may be formed beneath the first surface 712 of the fourth substrate 510, and thus the first surface 712 of the fourth substrate 710 may be an active surface. The circuit device may include circuit patterns, which may be covered by the seventh insulating interlayer.

The eighth insulating interlayer 730 may contain a fourth wiring structure 740 therein. The fourth wiring structure 740 may include, e.g., wirings, vias, contact plugs, etc., at a plurality of levels, however, the fourth wiring structure 740 is shown as a single structure in FIG. 1 for the brevity of the drawing.

The fourth bonding layer 780 may be formed beneath the eighth insulating interlayer 730, and may cover a sidewall of the fourth bonding pattern 785, as illustrated in FIG. 1. The fourth bonding pattern 785 may contact a portion of the fourth wiring structure 740 in the eighth insulating interlayer 730, and may be electrically connected thereto. The fourth bonding pattern 785 may include a metal, e.g., copper, and the fourth bonding layer 780 may include an insulating nitride, e.g., silicon carbonitride or an oxide, e.g., silicon oxide.

Each of the seventh insulating interlayer and the eighth insulating interlayer 730 may include, e.g., silicon oxide or a low-k dielectric material, e.g., an oxide doped with carbon or fluorine. The wirings, the vias and the contact plugs included in the fourth wiring structure 740 may include a conductive material, e.g., a metal, a metal nitride, a metal silicide, etc.

The third semiconductor chip structure included in each of the lower and upper semiconductor chip stack structures 910 and 920 may include the third semiconductor chips 500 stacked in the vertical direction by a hybrid copper bonding (HCB) process. That is, the second bonding layer 580 of a first one of the third semiconductor chips 500 may be bonded to the third bonding layer 590 of a second one of the third semiconductor chips 500 that is disposed under the first one of the third semiconductor chips 500, and the second bonding pattern 585 in the second bonding layer 580 may contact the third bonding pattern 595 in the third bonding layer 590.

Additionally, the second semiconductor chip 300 included in each of the lower and upper semiconductor chip stack structures 910 and 920 may be bonded to a lowermost one of the semiconductor chips 500 included in the third semiconductor chip structure by an HCB process. That is, the second bonding layer 580 of the third semiconductor chip 500 and the first bonding layer 390 of the second semiconductor chip 300 may be bonded to each other, and the second bonding pattern 585 in the second bonding layer 580 and the first bonding pattern 395 in the first bonding layer 390 may contact each other.

Further, the fourth semiconductor chip 700 may be bonded to an uppermost one of the third semiconductor chips 500 of the third semiconductor chip structure included in the upper semiconductor chip stack structure 920 by an HCB process. That is, the fourth bonding layer 780 of the fourth semiconductor chip 700 and the third bonding layer 590 of the third semiconductor chip 500 may be bonded to each other, and the fourth bonding pattern 785 in the fourth bonding layer 780 and the third bonding pattern 595 in the third bonding layer 590 may contact each other.

The first semiconductor chip 100 and the second semiconductor chip 300 included in the lower semiconductor chip stack structure 910 may be bonded to each other by a thermal compression bonding (TCB) process. That is, the second conductive connection member 350 in the second semiconductor chip 300 may contact the conductive pad 175 in the first semiconductor chip 100.

Additionally, an uppermost one of the third semiconductor chips 500 of the third semiconductor chip structure included in the lower semiconductor chip stack structure 910 and the second semiconductor chip 300 included in the upper semiconductor chip stack structure 920 may be bonded to each other by a TCB process. That is, the second conductive connection member 350 in the second semiconductor chip 300 may contact the third bonding pattern 595 in the third semiconductor chip 500.

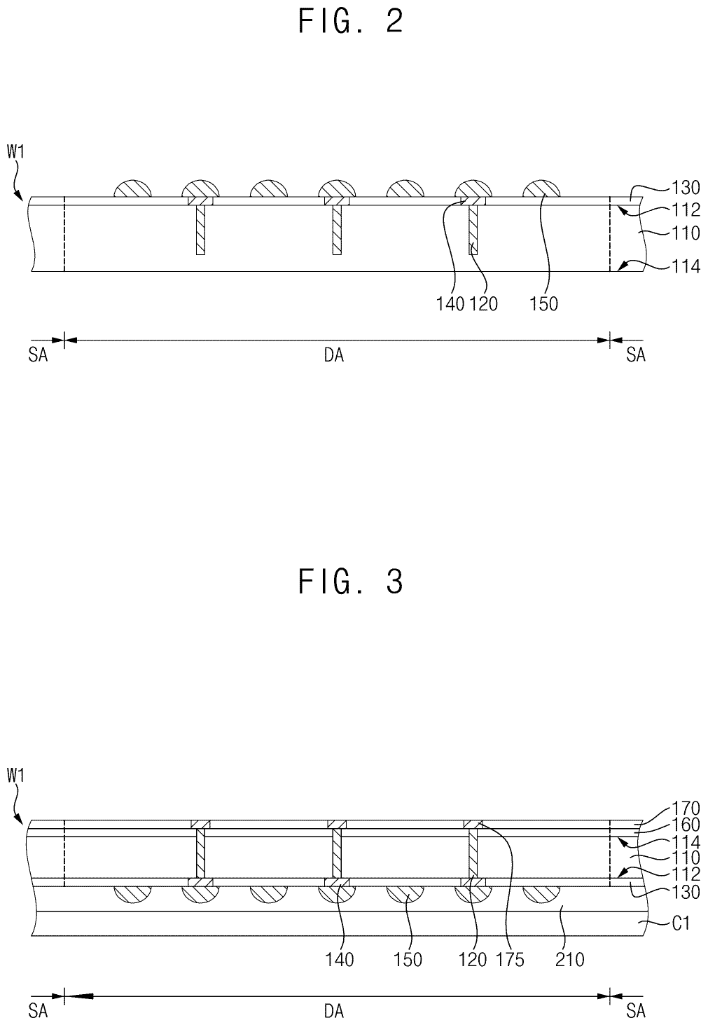

As illustrated below with reference to FIGS. 2 to 11, in the third semiconductor chip structure in each of the lower and upper semiconductor chip stack structures 910 and 920, as the number of the third semiconductor chips 500 stacked in the vertical direction is limited, an accumulated amount of distortions is not so large, and thus no void may be formed between the second and third bonding layers 580 and 590 included in respective ones of the third semiconductor chips 500 disposed at high levels, so that the third semiconductor chips 500 may be well bonded to each other.

The first semiconductor chip 100 and the lower semiconductor chip stack structure 910, and the lower semiconductor chip stack structure 910 and the upper semiconductor chip stack structure 920 may be bonded to each other by a TCB process, and thus may have a structural stability.

In example embodiments, the second semiconductor chip 300 having the same function and structure as those of the third semiconductor chip 500 may have a vertical thickness less than a vertical thickness of the third semiconductor chip 500, and thus may neutralize an increase of the vertical thickness that may be caused by the bonding of the first semiconductor chip 100 and the lower semiconductor chip stack structure 910 by the TCB process, and the bonding of the lower semiconductor chip stack structure 910 and the upper semiconductor chip stack structure 920 by the TCB process.

The first mold layer 610 may be formed on the second semiconductor chip 300 included in the lower semiconductor chip stack structure 910, and may cover a sidewall of the third semiconductor chip structure. Additionally, the first mold layer 610 may be formed on the second semiconductor chip 300 included in the upper semiconductor chip stack structure 920, and may cover a sidewall of the third semiconductor chip structure.

The second mold layer 620 may be formed on the first semiconductor chip 100, and may cover a sidewall of the second semiconductor chip 300 included in each of the lower and upper semiconductor chip stack structures 910 and 920, sidewalls and upper surfaces of the first and second mold layers 610 and 620, and a sidewall of the fourth semiconductor chip 700. Additionally, the second mold layer 620 may fill a space between the first semiconductor chip 100 and the lower semiconductor chip stack structure 910 and a space between the lower semiconductor chip stack structure 910 and the upper semiconductor chip stack structure 920.

Each of the first and second mold layers 610 and 620 may include, e.g., epoxy molding compound (EMC), non-conductive film (NCF), molding underfill (MUF), etc. The first and second mold layers 610 and 620 may include substantially the same material to be merged with each other, or different materials from each other.

FIGS. 2 to 11 are cross-sectional views illustrating a method of manufacturing a semiconductor package in accordance with example embodiments.

Referring to FIG. 2, a first wafer W1 may be provided.

In example embodiments, the first wafer W1 may include a first substrate 110 having first and second surfaces 112 and 114 opposite to each other in the vertical direction. Additionally, the first wafer W1 may include a plurality of die regions DA and a scribe lane region SA surrounding each of the die regions DA. The first wafer W1 may be cut along the scribe lane region SA by a sawing process to be singulated into a plurality of first semiconductor chips.

In the die region DA, a circuit device may be formed on the first surface 112 of the first substrate 110. The circuit device may include a logic device. The circuit device may include circuit patterns, and a first insulating interlayer may be formed on the first surface 112 of the first substrate 110 to cover the circuit patterns.

A second insulating interlayer 130 may be formed on the first insulating interlayer, and may contain a first wiring structure 140 therein. The first wiring structure 140 may include, e.g., wirings, vias, contact plugs, etc., however, the first wiring structure 140 is shown as a single structure in FIG. 2 for the brevity of the drawing.

A first conductive connection member 150 may be formed on the second insulating interlayer 130, and may contact a portion of the first wiring structure 140 to be electrically connected thereto.

A first through electrode 120 extending through an upper portion of the first substrate 110 in the vertical direction and contacting a portion of the circuit patterns to be electrically connected thereto may be formed. In example embodiments, a plurality of first through electrodes 120 may be spaced apart from each other in the horizontal direction.

Referring to FIG. 3, a first temporary bonding layer 210 may be attached on a first carrier substrate C1, the first carrier substrate C1 may be bonded to the first wafer W1 such that the first temporary bonding layer 210 may contact an upper surface of the second insulating interlayer 130 to cover the first conductive connection member 150, and a structure including the first carrier substrate C1 and the first wafer W1 may be overturned.

The first carrier substrate C1 may include, e.g., a metallic or non-metallic plate, a silicon substrate, a glass substrate, etc. The first temporary bonding layer 210 may include a material that may lose adhesion by irradiation of light or heating. In an example embodiment, the first temporary bonding layer 210 may include glue.

A portion of the first substrate 110 adjacent to the second surface 114 of the first substrate 110 may be removed by, e.g., a grinding process to expose an upper portion of the first through electrode 120, a first protective layer structure may be formed on the second surface 114 of the first substrate 110 to cover the first through electrode 120, and a planarization process may be performed on the first protective layer structure until an upper surface of the first through electrode 120 is exposed, so as to form a first protective pattern structure 160.

In example embodiments, the planarization process may include a chemical mechanical polishing (CMP) process and/or an etch back process.

A conductive pad 175 may be formed to contact the first through electrode 120, and a passivation layer 170 may be formed on the first protective pattern structure 160 to cover a sidewall of the conductive pad 175. A plurality of conductive pads 175 may be spaced apart from each other in the horizontal direction according to the layout of the first through electrodes 120.

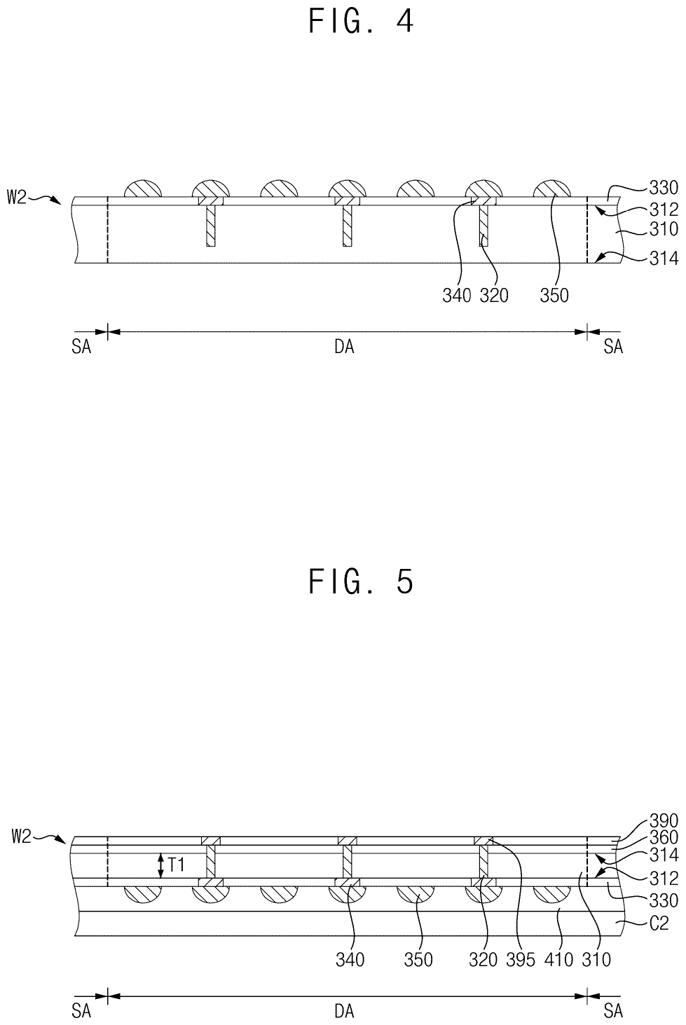

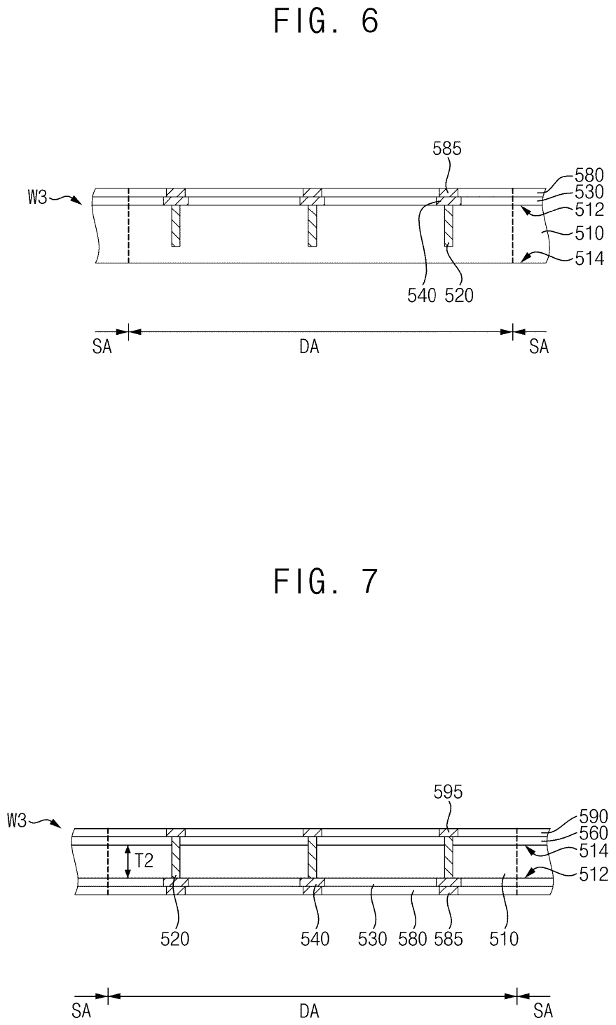

Referring to FIG. 4, a second wafer W2 may be provided.

In example embodiments, the second wafer W2 may include a second substrate 310 having first and second surfaces 312 and 314 opposite to each other in the vertical direction. Additionally, the second wafer W2 may include a plurality of die regions DA and a scribe lane region SA surrounding each of the die regions DA. The second wafer W2 may be cut along the scribe lane region SA by a sawing process to be singulated into a plurality of second semiconductor chips.

In the die region DA, a circuit device may be formed on the first surface 312 of the second substrate 310. The circuit device may include a memory device. The circuit device may include circuit patterns, and a third insulating interlayer may be formed on the first surface 312 of the second substrate 310 to cover the circuit patterns.

A fourth insulating interlayer 330 may be formed on the third insulating interlayer, and may contain a second wiring structure 340 therein. The second wiring structure 340 may include, e.g., wirings, vias, contact plugs, etc., however, the second wiring structure 340 is shown as a single structure in FIG. 4 for the brevity of the drawing.

A second conductive connection member 350 may be formed on the fourth insulating interlayer 330, and may contact a portion of the second wiring structure 340 to be electrically connected thereto.

A second through electrode 320 extending through an upper portion of the second substrate 310 in the vertical direction and contacting a portion of the circuit patterns to be electrically connected thereto may be formed. In example embodiments, a plurality of second through electrodes 320 may be spaced apart from each other in the horizontal direction.

Referring to FIG. 5, a second temporary bonding layer 410 may be attached on a second carrier substrate C2, the second carrier substrate C2 may be bonded to the second wafer W2 such that the second temporary bonding layer 410 may contact an upper surface of the fourth insulating interlayer 330 to cover the second conductive connection member 350, and a structure including the second carrier substrate C2 and the second wafer W2 may be overturned.

The second carrier substrate C2 may include, e.g., a metallic or non-metallic plate, a silicon substrate, a glass substrate, etc. The second temporary bonding layer 410 may include a material that may lose adhesion by irradiation of light or heating. In an example embodiment, the second temporary bonding layer 410 may include glue.

A portion of the second substrate 310 adjacent to the second surface 314 of the second substrate 310 may be removed by, e.g., a grinding process to expose an upper portion of the second through electrode 320, a second protective layer structure may be formed on the second surface 314 of the second substrate 310 to cover the second through electrode 320, and a planarization process may be performed on the second protective layer structure until an upper surface of the second through electrode 320 is exposed, so as to form a second protective pattern structure 360.

During the grinding process, an upper portion of the second through electrode 320 may also be removed, and after the grinding process, the second substrate 310 may have a first thickness T1 in the vertical direction.

A first bonding layer 390 containing a first bonding pattern 395 may be formed on the second protective pattern structure 360 and the second through electrode 320. In example embodiments, a plurality of first bonding patterns 395 may be spaced apart from each other in the first direction, and the first bonding patterns 395 may contact upper surfaces of the second through electrodes 320, respectively, to be electrically connected thereto.

Referring to FIG. 6, a third wafer W3 may be provided.

In example embodiments, the third wafer W3 may include a third substrate 510 having first and second surfaces 512 and 514 opposite to each other in the vertical direction. Additionally, the third wafer W3 may include a plurality of die regions DA and a scribe lane region SA surrounding each of the die regions DA. The third wafer W3 may be cut along the scribe lane region SA by a sawing process to be singulated into a plurality of third semiconductor chips.

In the die region DA, a circuit device may be formed on the first surface 512 of the third substrate 510. The circuit device may include a memory device. The circuit device may include circuit patterns, and a fifth insulating interlayer may be formed on the first surface 512 of the third substrate 510 to cover the circuit patterns.

A sixth insulating interlayer 530 may be formed on the fifth insulating interlayer, and may contain a third wiring structure 540 therein. The third wiring structure 540 may include, e.g., wirings, vias, contact plugs, etc., however, the third wiring structure 540 is shown as a single structure in FIG. 6 for the brevity of the drawing.

A second bonding layer 580 containing a second bonding pattern 585 may be formed on the sixth insulating interlayer 530. In example embodiments, a plurality of second bonding patterns 585 may be spaced apart from each other in the first direction, and each of the second bonding patterns 585 may contact an upper surface of a portion of the third wiring structure 540 to be electrically connected thereto.

A third through electrode 520 extending through an upper portion of the third substrate 510 in the vertical direction and contacting a portion of the circuit patterns to be electrically connected thereto may be formed. In example embodiments, a plurality of third through electrodes 520 may be spaced apart from each other in the horizontal direction.

Referring to FIG. 7, after overturning the third wafer W3, a portion of the third substrate 510 adjacent to the second surface 514 of the third substrate 510 may be removed by, e.g., a grinding process to expose an upper portion of the third through electrode 520, a third protective layer structure may be formed on the second surface 514 of the third substrate 510 to cover the third through electrode 520, and a planarization process may be performed on the third protective layer structure to form a third protective pattern structure 560.

By the grinding process, the third substrate 510 may have a second thickness T2 in the vertical direction. In an example embodiment, the second thickness T2 may be greater than the first thickness T1.

A third bonding layer 590 containing a third bonding pattern 595 may be formed on the third protective pattern structure 560 and the third through electrode 520. In example embodiments, a plurality of third bonding patterns 595 may be spaced apart from each other in the horizontal direction, and the third bonding patterns 595 may contact upper surfaces of the third through electrodes 520, respectively, to be electrically connected thereto.

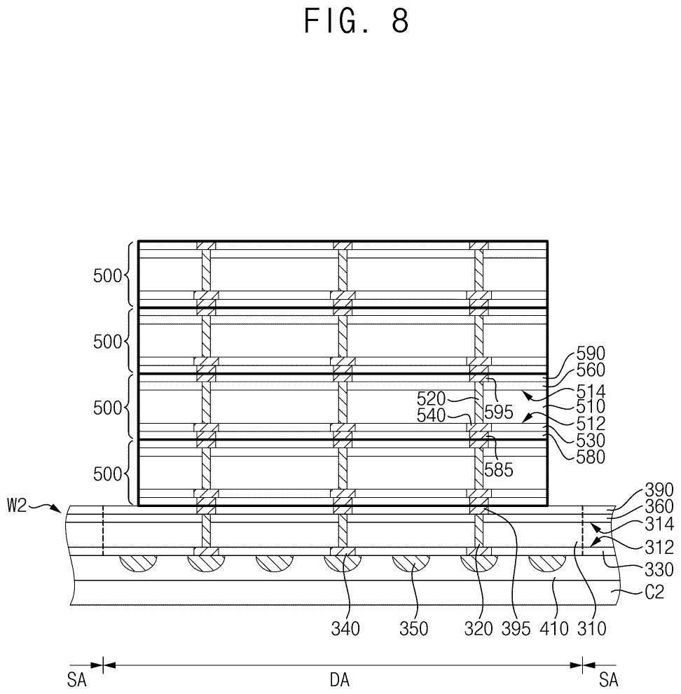

Referring to FIG. 8, after cutting the third wafer W3 along the scribe lane region SA by a sawing process into third semiconductor chips 500, each of the third semiconductor chips 500 and the second wafer W2 may be bonded to each other by an HCB process.

Particularly, the second bonding layer 580 in the third semiconductor chip 500 may contact the first bonding layer 390 in the second wafer W2 so that the third semiconductor chip 500 and the second wafer W2 may be bonded to each other, and the second bonding pattern 585 in the second bonding layer 580 and the first bonding pattern 395 in the first bonding layer 390 may contact each other.

In example embodiments, a plurality of third semiconductor chips 500 may be stacked in the vertical direction on the second wafer W2, and the third semiconductor chips 500 may be bonded to each other by an HCB process. That is, the second bonding layer 580 included in a first one of the third semiconductor chips 500 disposed at a relatively high level and the third bonding layer 590 included in a second one of the third semiconductor chips 500 disposed at a relatively low level may be bonded to each other, and the second bonding pattern 585 in the second bonding layer 580 and the third bonding pattern 595 in the third bonding layer 590 may contact each other.

When the second wafer W2 and the third semiconductor chip 500 are bonded to each other by the HCB process or the third semiconductor chips 500 are bonded to each other by the HCB process, each of the third semiconductor chips 500 may be compressed so as to be partially distorted. Thus, if the number of the third semiconductor chips 500 stacked on the second wafer W2 increases, the distortions of the third semiconductor chips 500 may be accumulated so that void may be generated between the second and third bonding layers 580 and 590 included in neighboring ones of the third semiconductor chips 500, respectively, in the vertical direction, which may deteriorate the bonding state between the third semiconductor chips 500.

In example embodiments, the number of the third semiconductor chips 500 stacked in the vertical direction in the third semiconductor chip structure may be restricted to a given number, e.g., four, and thus an accumulated amount of the distortions of the third semiconductor chips 500 may not be so large that the void may not be generated between the second and third bonding layers 580 and 590 included in the neighboring ones of the third semiconductor chips 500 at high levels. Accordingly, the third semiconductor chips 500 may be well bonded to each other.

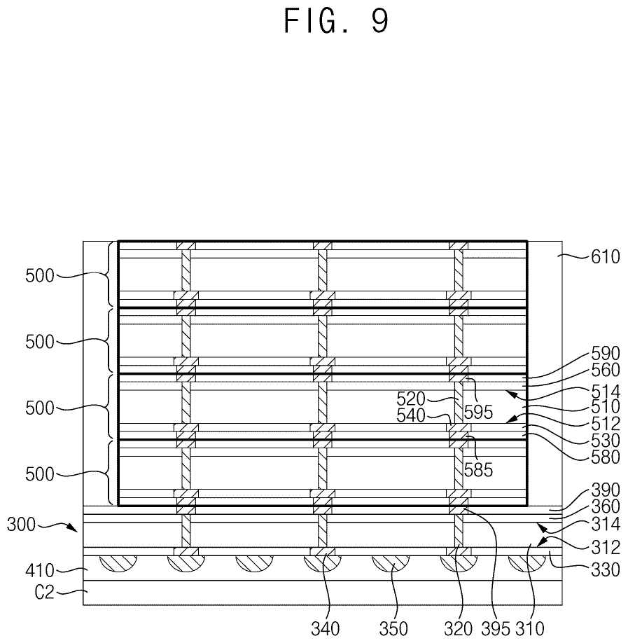

Referring to FIG. 9, a first mold layer may be formed on the second wafer W2 to cover the third semiconductor chip structure, and a planarization process may be performed on the first mold layer to expose an upper surface of the third semiconductor chip structure, and thus a first mold layer 610 covering a sidewall of the third semiconductor chip structure may be formed.

In example embodiments, the planarization process may include a chemical mechanical polishing (CMP) process.

The second wafer W2 may be cut along the scribe lane region SA by, e.g., a sawing process to be singulated into a plurality of second semiconductor chips 300.

During the sawing process, the first mold layer 610 may also be cut to be formed on each of the second semiconductor chips 300 to cover the sidewall of the third semiconductor chip structure.

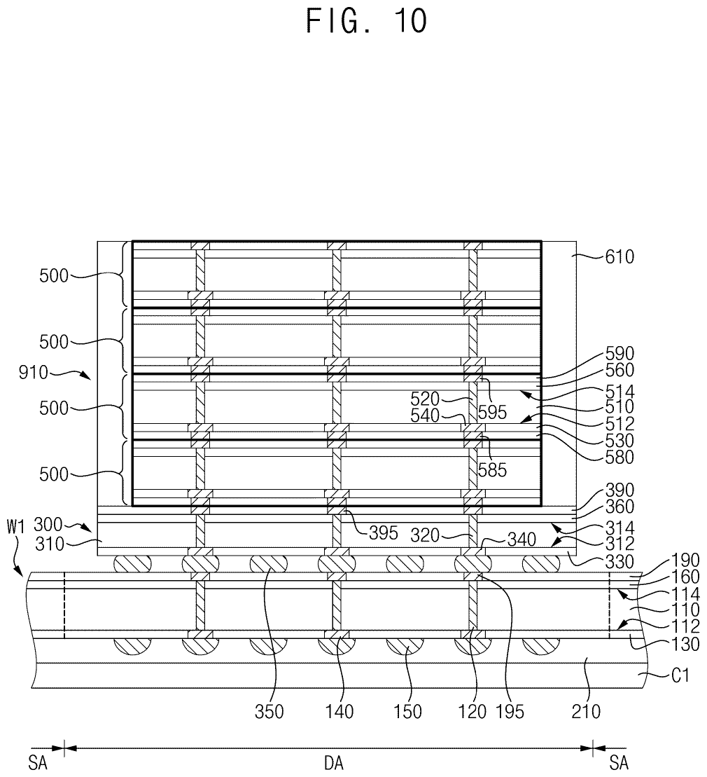

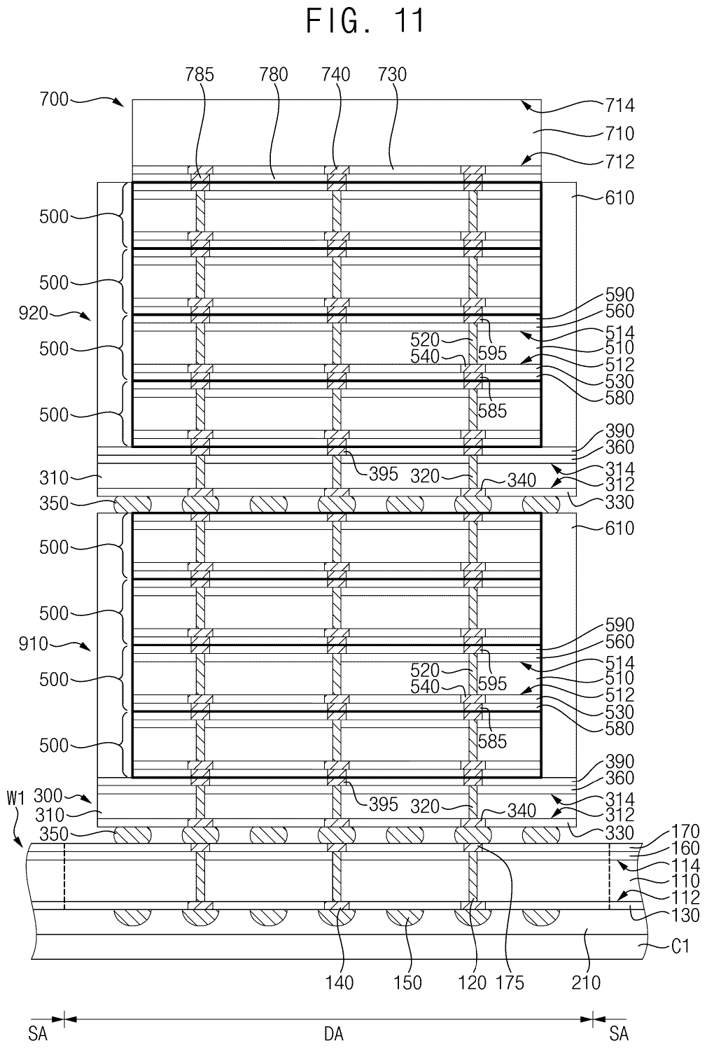

Referring to FIG. 10, the second temporary bonding layer 410 attached to the second carrier substrate C2 may be separated from the fourth insulating interlayer 330 and the second conductive connection member 350 so that the second carrier substrate C2 may be separated from the second semiconductor chip 300, and the second semiconductor chip 300 bonded to the third semiconductor chip structure may be bonded to the first wafer W1 by a thermal compression bonding (TCB) process.

The second conductive connection member 350 of the second semiconductor chip 300 may contact the conductive pad 175 of the first wafer W1 so that the second semiconductor chip 300 and the first wafer W1 may be bonded to each other.

The second semiconductor chip 300 and the third semiconductor chip structure stacked on the first wafer W1 may collectively form a lower semiconductor chip stack structure 910.

Referring to FIG. 11, processes substantially the same as or similar to those illustrated with respect to FIG. 10 may be performed, so that an upper semiconductor chip stack structure 920 including the third semiconductor chip structure and the second semiconductor chip 300 bonded to each other may be formed, and the upper semiconductor chip stack structure 920 may be stacked on and bonded to the lower semiconductor chip stack structure 910.

In example embodiments, the second conductive connection member 350 of the second semiconductor chip 300 included in the upper semiconductor chip stack structure 920 may contact the third bonding layer 590 of an uppermost one of the third semiconductor chips 500 included in the lower semiconductor chip stack structure 910, so that the lower and upper semiconductor chip stack structures 910 and 920 may be bonded to each other.

A fourth semiconductor chip 700 may be stacked on the upper semiconductor chip stack structure 920.

The fourth semiconductor chip 700 may include a fourth substrate 710 having first and second surfaces 712 and 714 opposite to each other in the vertical direction. A circuit device may be formed beneath the first surface 712 of the fourth substrate 710. The circuit device may include a memory device. The circuit device may include circuit patterns, and a seventh insulating interlayer may be formed beneath the first surface 712 of the fourth substrate 710 to cover the circuit patterns.

An eighth insulating interlayer 730 may be formed on the seventh insulating interlayer, and may contain a fourth wiring structure 740 therein. The fourth wiring structure 740 may include, e.g., wirings, vias, contact plugs, etc., however, the fourth wiring structure 740 is shown as a single structure in FIG. 11 for the brevity of the drawing.

In an example embodiment, the fourth semiconductor chip 700 may be bonded to the upper semiconductor chip stack structure 920 by an HCB process. That is, a fourth bonding layer 780 containing a fourth bonding pattern 785 may be formed beneath the eighth insulating interlayer 730, and may contact the third bonding layer 590 of an uppermost one of the third semiconductor chips 500 included in the upper semiconductor chip stack structure 920. The fourth bonding pattern 785 in the fourth bonding layer 780 may contact the third bonding pattern 595 in the third bonding layer 590.

Referring to FIG. 1 again, a second mold layer may be formed on the first wafer W1 to cover the lower semiconductor chip stack structure 910, the upper semiconductor chip stack structure 920 and the fourth semiconductor chip 700, and a planarization process may be performed on the second mold layer until an upper surface of the fourth semiconductor chip 700 is exposed, and thus a second mold layer 620 covering sidewalls of the lower semiconductor chip stack structure 910, the upper semiconductor chip stack structure 920 and the fourth semiconductor chip 700 may be formed.

The first wafer W1 may be cut along the scribe lane region SA by, e.g., a sawing process to be singulated into a plurality of first semiconductor chips 100. During the sawing process, the second mold layer 620 may also be cut, and may be formed on each of the first semiconductor chips 100 to cover the sidewalls of the lower semiconductor chip stack structure 910, the upper semiconductor chip stack structure 920 and the fourth semiconductor chip 700.

As illustrated above, the third semiconductor chips 500 included in each of the lower and upper semiconductor chip stack structures 910 and 920 may be bonded to each other by an HCB process, however, each of the lower and upper semiconductor chip stack structures 910 and 920 may include only a restricted number of the third semiconductor chips 500. Thus, a void, which may be formed between the third semiconductor chips 500 when a large number of the third semiconductor chips 500 are bonded to each other by an HCB process, may not be formed.

That is, the third semiconductor chips 500 stacked on the first semiconductor chip 100 may be divided into a several groups, ones of the third semiconductor chips 500 in each group may be bonded to each other by an HCB process, while the groups may be bonded to each other by a TCB process. Thus, the semiconductor package may have a reduced thickness by the HCB process, and may also have a structural stability by the TCB process.

Each group may include the second semiconductor chip 300 and a plurality of third semiconductor chips 500 stacked on the second semiconductor chip 300, and a lowermost one of the third semiconductor chips 500 and the second semiconductor chip 300 may be bonded to each other by an HCB process.

In example embodiments, the second semiconductor chip 300 may have function and structure substantially the same as those of the third semiconductor chip 500, however, a vertical thickness of the second semiconductor chip 300, that is, the first thickness T1 may be less than a vertical thickness of the third semiconductor chip 500, that is, the second thickness T2. Thus, even though the groups are stacked in the vertical direction by a TCB process, an increase of the vertical thickness may be neutralized by the small thickness of the second semiconductor chip 300.

The semiconductor package may include two semiconductor chip stack structures, that is, the lower and upper semiconductor chip stack structures 910 and 920 stacked in the vertical direction on the first semiconductor chip 100, however, the inventive concept may not be limited thereto, and the semiconductor package may include more than two semiconductor chip stack structures on the first semiconductor chip 100.

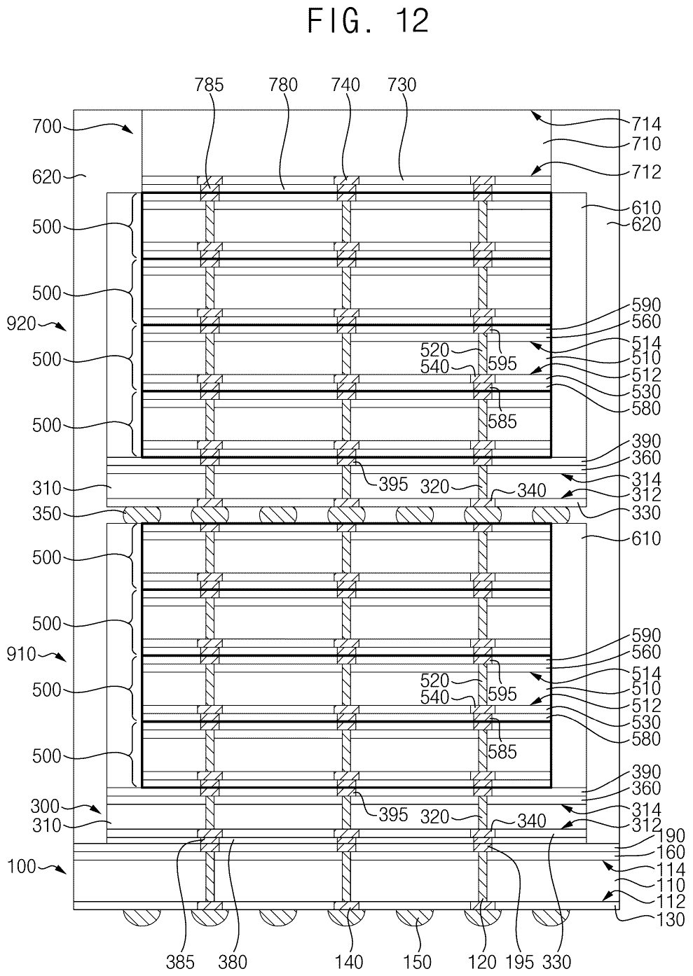

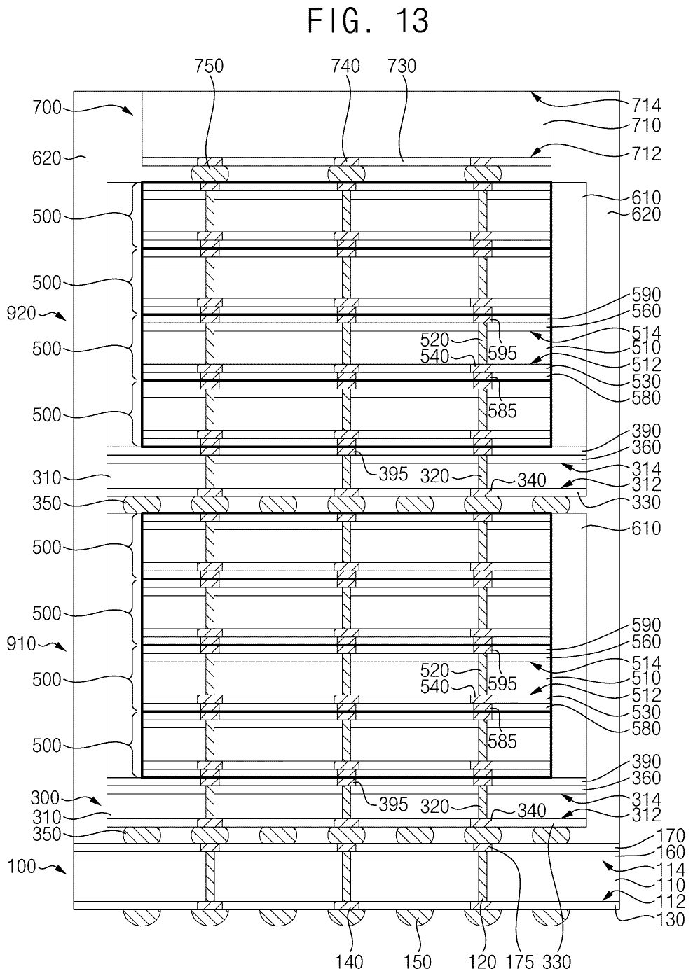

FIGS. 12 to 14 are cross-sectional views illustrating semiconductor packages in accordance with example embodiments, which may correspond to FIG. 1.

Each of the semiconductor packages may be substantially the same as or similar to that of FIG. 1, except for some elements, and thus repeated explanations are omitted herein.

Referring to FIG. 12, the first semiconductor chip 100 and the lower semiconductor chip stack structure 910 may be bonded to each other not by a TCB process but by an HCB process.

Thus, the first semiconductor chip 100 may include, instead of the conductive pad 175 and the passivation layer 170, a fifth bonding layer 190 containing a fifth bonding pattern 195 that may contact an upper surface of the first through electrode 120, and the second semiconductor chip 300 may include, instead of the second conductive connection member 350, a sixth bonding layer 380 containing a sixth bonding pattern 385 that may contact a portion of the second wiring structure 340. The fifth and sixth bonding layers 190 and 380 may be bonded to each other, and the fifth and sixth bonding patterns 195 and 385 may contact each other.

Referring to FIG. 13, the fourth semiconductor chip 700 and the upper semiconductor chip stack structure 920 may be bonded to each other not by an HCB process but by a TCB process.

Thus, the fourth semiconductor chip 700 may include, instead of the fourth bonding layer 780 and the fourth bonding pattern 785, a third conductive connection member 750. The third conductive connection member 750 may contact the third bonding pattern 595 of the uppermost one of the third semiconductor chips 500 included in the upper semiconductor chip stack structure 920.

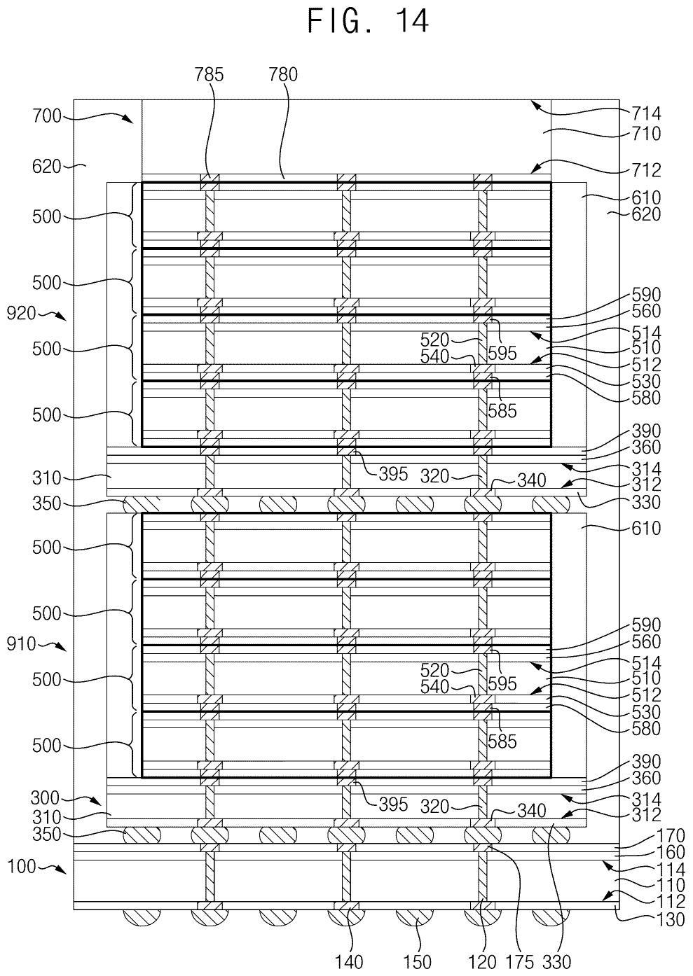

Referring to FIG. 14, the fourth semiconductor chip 700 may not have function and structure that are substantially the same as or similar to those of the third semiconductor chip 500, but may be a dummy chip.

Thus, the fourth semiconductor chip 700 may not include the seventh insulating interlayer, the eighth insulating interlayer 730, the circuit device and the fourth wiring structure 740, and may include only the fourth substrate 710.

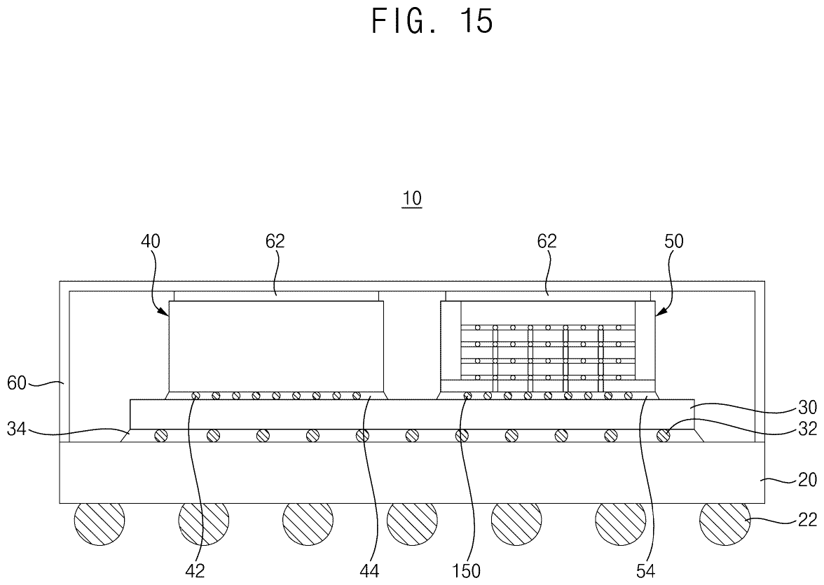

FIG. 15 is a cross-sectional view illustrating an electronic device in accordance with example embodiments.

This electronic device may include the semiconductor package shown in FIG. 1 as a second semiconductor device 50, however, the inventive concept may not be limited thereto, and the second semiconductor chip 50 may also include one the semiconductor packages of FIGS. 12 to 14.

Referring to FIG. 15, an electronic device 10 may include a package substrate 20, an interposer 30, a first semiconductor device 40 and the second semiconductor device 50. The electronic device 10 may further include first, second and third underfill members 34, 44 and 54, a heat slug 60 and a heat dissipation member 62.

In example embodiments, the electronic device 10 may be a memory module having a 2.5D package structure, and thus may include the interposer 30 for electrically connecting the first and second semiconductor devices 40 and 50 to each other.

In example embodiments, the first semiconductor device 40 may include a logic device, and the second semiconductor device 50 may include a memory device. The logic device may be an application-specific integrated circuit (ASIC) chip including, e.g., a central processing unit (CPU), a graphics processing unit (GPU), a micro-processor, a micro-controller, an application processor (AP), a digital signal processing core, etc. The memory device may be the semiconductor package of FIG.

In example embodiments, the package substrate 20 may have an upper surface and a lower surface opposite to each other in the vertical direction. For example, the package substrate 20 may be a printed circuit board (PCB). The printed circuit board may be a multi-layer circuit board having various circuits therein.

The interposer 30 may be mounted on the package substrate 20 through a fifth conductive connection member 32. In example embodiments, a planar area of the interposer 30 may be smaller than a planar area of the package substrate 20. The interposer 30 may be disposed within an area of the package substrate 20 in a plan view.

The interposer 30 may be a silicon interposer or a redistribution interposer having a plurality of wirings therein. The first semiconductor device 40 and the second semiconductor device 50 may be connected to each other through the wirings in the interposer 30 or electrically connected to the package substrate 20 through the fifth conductive connection member 32. The fifth conductive connection member 32 may include, e.g., a micro-bump. The silicon interposer may provide a high-density interconnection between the first and second semiconductor devices 40 and 50.

The first semiconductor device 40 may be disposed on the interposer 30. The first semiconductor device 40 may be mounted on and bonded to the interposer 30 by a TCB process. In this case, the first semiconductor device 40 may be mounted on the interposer 30 such that an active surface on which conductive pads are formed may face downwardly toward the interposer 30. The conductive pads of the first semiconductor device 40 may be electrically connected to conductive pads of the interposer 30 through a sixth conductive connection member 42. For example, the sixth conductive connection member 42 may include, e.g., a micro-bump.

Alternatively, the first semiconductor device 40 may be mounted on the interposer 30 by a wire bonding process, and in this case, the active surface of the first semiconductor device 40 may face upwardly.

The second semiconductor device 50 may be disposed on the interposer 30, and may be spaced apart from the first semiconductor device 40 in the horizontal direction. The second semiconductor device 50 may be mounted on and bonded to the interposer 30 by, e.g., a TCB process. In this case, conductive pads of the second semiconductor device 50 may be electrically connected to conductive pads of the interposer 30 by the first conductive connection member 150.

Although a single first semiconductor device 40 and a single second semiconductor device 50 are disposed on the interposer 30, however, the inventive concept may not be limited thereto, and a plurality of first semiconductor devices 40 and/or a plurality of second conductive devices 50 may be disposed on the interposer 30.

In example embodiments, the first underfill member 34 may fill a space between the interposer 30 and the package substrate 20, and the second and third underfill members 44 and 54 may fill a space between the first semiconductor device 40 and the interposer 30 and a space between the second semiconductor device 50 and the interposer 30, respectively.

The first to third underfill members 34, 44 and 54 may include a material having a relatively high fluidity to effectively fill a small space between the first and second semiconductor devices 40 and 50 and the interposer 30 and a small space between the interposer 30 and the package substrate 20. For example, each of the first and second underfill members 34, 44 and 54 may include an adhesive containing an epoxy material.

In example embodiments, the heat slug 60 may be formed on the package substrate 20 to thermally contact the first and second semiconductor devices 40 and 50. The heat dissipation member 62 may be disposed on an upper surface of each of the first and second semiconductor devices 40 and 50, and may include, e.g., thermal interface material (TIM). The heat slug 60 may thermally contact the first and second semiconductor devices 40 and 50 via the heat dissipation member 62.

A conductive pad may be formed at a lower portion of the package substrate 20, and a fourth conductive connection member 22 may be disposed beneath the conductive pad. In example embodiments, a plurality of fourth conductive connection members 22 may be spaced apart from each other in the horizontal direction. The fourth conductive connection member 22 may be, e.g., a solder ball. The electronic device 10 may be mounted on a module board via the sixth conductive connection members 22 to form a memory module.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims.

What is claimed is:

1. A semiconductor package comprising:
a buffer die;
memory die stack structures sequentially stacked on the buffer die in a first direction, each of the memory die stack structures comprising a base core die and middle core dies stacked on the base core die in the first direction;
a first mold layer on the base core die of each of the memory die stack structures and on sidewalls of the middle core dies; and
a second mold layer on the buffer die, on sidewalls of the base core dies, and on a sidewall of the first mold layer,
wherein the buffer die has a first planar area, the base core die has a second planar area smaller than the first planar area, and wherein each of the middle core dies has a third planar area smaller than the second planar area.

2. The semiconductor package according to claim 1, further comprising a top core die stacked on an uppermost one of the memory die stack structures,
wherein the second mold layer is on a sidewall of the top core die.

3. The semiconductor package according to claim 1, wherein the base core die of each of the memory die stack structures comprises a conductive bump at a lower portion thereof, and
wherein neighboring ones of the memory die stack structures in the first direction are bonded to each other by the conductive bump.

4. The semiconductor package according to claim 3, wherein the buffer die and a lowermost one of the memory die stack structures are bonded to each other by the conductive bump.

5. The semiconductor package according to claim 1, wherein each of the middle core dies in each of the memory die stack structures comprises:
a first bonding layer comprising a first bonding pattern, wherein the first bonding layer is beneath a lower surface of each of the middle core dies; and
a second bonding layer comprising a second bonding pattern, wherein the second bonding layer is on an upper surface of each of the middle core dies,
wherein neighboring ones of the middle core dies in the first direction are bonded to each other by the first and second bonding patterns and the first and second bonding layers.

6. The semiconductor package according to claim 5, wherein each of the first and second bonding patterns comprises copper, and each of the first and second bonding layers comprises silicon carbonitride.

7. The semiconductor package according to claim 1, wherein each of the middle core dies comprises:
a substrate having opposite first and second surfaces;
a through electrode extending through the substrate, the through electrode comprising a protrusion portion that protrudes over the second surface of the substrate;
a protective pattern structure on the second surface of the substrate, the protective pattern structure on a sidewall of the protrusion portion of the through electrode; and
a wiring structure beneath the first surface of the substrate.

8. The semiconductor package according to claim 1, wherein the base core die comprises:
a substrate comprising opposite first and second surfaces;
a through electrode extending through the substrate, the through electrode comprising a protrusion portion that extends through the second surface of the substrate;
a protective pattern structure on the second surface of the substrate and on a sidewall of the protrusion portion of the through electrode; and
a wiring structure beneath the first surface of the substrate.

9. The semiconductor package according to claim 1, wherein a thickness in the first direction of the base core die is smaller than a thickness in the first direction of each of the middle core dies.

10. The semiconductor package according to claim 1, wherein the base core dies in the memory die stack structures have substantially a same planar area, and the middle core dies in the memory die stack structures have substantially a same planar area.

11. A semiconductor package comprising:
a lower semiconductor chip stack structure comprising:
a first semiconductor chip comprising a logic device;
a second semiconductor chip on and bonded to the first semiconductor chip, the second semiconductor chip comprising a memory device; and
third semiconductor chips stacked on the second semiconductor chip in a first direction, each of the third semiconductor chips comprising a memory device;
an upper semiconductor chip stack structure comprising:
a fourth semiconductor chip on and bonded to the lower semiconductor chip stack structure, the fourth semiconductor chip comprising a memory device; and
fifth semiconductor chips stacked on the fourth semiconductor chip in the first direction, each of the fifth semiconductor chips comprising a memory device; and
a sixth semiconductor chip on and bonded to the upper semiconductor chip stack structure, the sixth semiconductor chip having a thickness in the first direction that is greater than a thickness of each of the third and fifth semiconductor chips,
wherein:
the lower semiconductor chip stack structure and the upper semiconductor chip stack structure are bonded to each other by a conductive bump,
the third semiconductor chips are bonded to each other by a first bonding pattern and a first bonding layer containing the bonding pattern, and the fifth semiconductor chips are bonded to each other by a second bonding pattern and a second bonding layer containing the bonding pattern,
each of the third and fifth semiconductor chips comprises:
a substrate comprising opposite first and second surfaces, the first surface facing toward the first semiconductor chip; and
wherein the memory device of each of the third and fifth semiconductor chips is beneath the second surface of the substrate.

12. The semiconductor package according to claim 11, wherein a planar area of the second semiconductor chip is greater than a planar area of each of the third semiconductor chips, and a planar area of the fourth semiconductor chip is greater than a planar area of each of the fifth semiconductor chips.

13. The semiconductor package according to claim 11, wherein a thickness in the first direction of the second semiconductor chip is smaller than a thickness in the first direction of each of the third semiconductor chips, and a thickness in the first direction of the fourth semiconductor chip is smaller than a thickness in the first direction of each of the fifth semiconductor chips.

14. The semiconductor package according to claim 11, further comprising:
a first mold layer on the second semiconductor chip and on sidewalls of the third semiconductor chips; and
a second mold layer on the fourth semiconductor chip and on sidewalls of the fifth semiconductor chips.

15. The semiconductor package according to claim 14, further comprising a third mold layer on the first semiconductor chip, on sidewalls of the second and fourth semiconductor chips, on a sidewall of the sixth semiconductor chip, and on sidewalls of the first and second mold layers.

16. A semiconductor package comprising:
a logic chip;
memory chip stack structures sequentially stacked on the logic chip in a first direction, each of the memory chip stack structures comprising a first memory chip and second memory chips stacked on the first memory chip in the first direction;
a third memory chip stacked on an uppermost one of the memory chip stack structures;
a first mold layer on the first memory chip of each of the memory chip stack structures and on sidewalls of the second memory chips; and
a second mold layer on the logic chip, on sidewalls of the first memory chips, on a sidewall of the third memory chip, and on a sidewall of the first mold layer,
wherein neighboring ones of the memory chip stack structures in the first direction are bonded to each other by a conductive bump, and
wherein neighboring ones of the second memory chips in the first direction are bonded to each other by a first bonding pattern and a first bonding layer containing the first bonding pattern, the first bonding pattern comprising copper.

17. The semiconductor package according to claim 16, wherein the first memory chip and a lowermost one of the memory chip stack structures are bonded to each other by a conductive bump.

18. The semiconductor package according to claim 16, wherein the third memory chip and an uppermost one of the memory chip stack structures are bonded to each other by a second bonding pattern and a second bonding layer containing the second bonding pattern, the second bonding pattern comprising copper.

19. The semiconductor package according to claim 16, wherein each of the second memory chips comprises:
a substrate comprising opposite first and second surfaces;
a through electrode extending through the substrate, the through electrode comprising a protrusion portion that extends through the second surface of the substrate;
a protective pattern structure on the second surface of the substrate, the protective pattern structure on a sidewall of the protrusion portion of the through electrode; and
a wiring structure beneath the first surface of the substrate.

20. The semiconductor package according to claim 16, wherein a thickness in the first direction of the first memory chip is smaller than a thickness in the first direction of each of the second memory chips.
